(19) United States
(12) Patent Application Publication
(10) Pub. No.: US 2015/0048394 A1
(43) Pub. Date: Feb. 19, 2015

(54) LIGHT EMITTING DEVICE PACKAGE AND METHOD OF MANUFACTURING THE SAME

(71) Applicant: SAMSUNG ELECTRONICS CO., LTD., Suwon-si (KR)

(72) Inventors: Hyun Wook SHIM, Suwon-si (KR); Young Sun KIM, Suwon-si (KR); Jae Sung HYUN, Hwaseong-si (KR)

(73) Assignee: SAMSUNG ELECTRONICS CO., LTD., Suwon-si (KR)

(21) Appl. No.: 14/297,233

(22) Filed: Jun. 5, 2014

(30) Foreign Application Priority Data
Aug. 16, 2013 (KR) 10-2013-0097196

(51) Int. Cl. H01L 33/62; H01L 33/52; H01L 33/60; H01L 33/08; H01L 33/50

(52) U.S. Cl. CPC H01L 33/62; H01L 33/08; H01L 33/502; H01L 33/60; H01L 33/52
USPC 257/89; 438/28

(57) ABSTRACT

A light emitting device package includes a body including a lead frame part, and a light emitting laminate disposed on the body and electrically connected to the lead frame part to emit light. The light emitting laminate has a multilayer structure in which a plurality of light emitting devices are stacked. In the plurality of light emitting devices, an upper light emitting device is stacked on a lower light emitting device such that vertex portions of the upper light emitting device do not overlap and are offset from vertex portions of the lower light emitting device, and portions of the lower light emitting device are externally exposed.

### CROSS-REFERENCE TO RELATED APPLICATION

This application claims priority to, and benefit of Korean Patent Application No. 2013-0097196 filed on Aug. 16, 2013, with the Korean Intellectual Property Office, the entire contents of which are hereby incorporated by reference.

### TECHNICAL FIELD

The present disclosure relates to a light emitting device package and a method of manufacturing the same.

### BACKGROUND

In accordance with an increase in demand for products having high degrees of luminance and light output, in the lighting device market, multi-chip packages having high light efficiency or reliability have been widely used. Existing multi-chip packages have a structure in which a plurality of LED chips are arranged horizontally on a bottom surface of the package and connected to one another by wire bonding. However, such a structure may be disadvantageous, in that the number of arranged chips may be restricted, depending on a size of the bottom surface, and, accordingly, the implementation of high degrees of luminance and light emissions may not be facilitated. In addition, a reduction in a package size may be limited, and thus miniaturization thereof according to recent trends is not easily performed.

### SUMMARY

An aspect of the present disclosure may provide a light emitting device package capable of realizing a multi-chip package by having a plurality of light emitting devices mounted therein, irrespective of a bottom surface size of the package, and capable of being easily miniaturized, and a method of manufacturing the same.

However, aspects of the present disclosure are not limited thereto, and may include objects and effects capable of being understood from descriptions and embodiments to be provided below, even though they are not specified.

One aspect of the present disclosure relates to a light emitting device package including a body including a lead frame part, and a light emitting laminate disposed on the body and electrically connected to the lead frame part, to emit light. The light emitting laminate has a multilayer structure in which a plurality of light emitting devices are stacked. In the plurality of light emitting devices, an upper light emitting device is stacked on a lower light emitting device such that vertex portions of the upper light emitting device do not overlap and are offset from vertex portions of the lower light emitting device, and portions of the lower light emitting device may be externally exposed.

In the plurality of light emitting devices, the upper light emitting device may be stacked on the lower light emitting device, while being disposed in a state in which the upper light emitting device is rotated with respect to the lower light emitting device, around an optical axis.

The upper light emitting device may be rotated with respect to the lower light emitting device within an angle range of 1 to 90°.

Each of the plurality of light emitting devices may include electrode pads at the vertex portions thereof externally exposed, the electrode pads being electrically connected to the lead frame part.

The plurality of light emitting devices may be configured to emit white light.

The plurality of light emitting devices may include a red light emitting diode (LED) chip, a green LED chip, and a blue LED chip.

Each of the plurality of light emitting devices may include a blue LED chip and may be covered by a wavelength conversion layer containing a phosphor.

The light emitting device package may further include a junction layer interposed between the plurality of the light emitting devices.

The light emitting device package may further include a filler layer disposed on one surface of the junction layer.

The body may have a recess portion having the plurality of light emitting devices disposed therein, the recess portion being provided with a reflective surface surrounding the plurality of light emitting devices.

The light emitting device package may further include an encapsulating part formed on the body to cover the plurality of light emitting devices.

Another aspect of the present disclosure encompasses a method of manufacturing a light emitting device package, including preparing a body including a lead frame part. A first light emitting device is mounted on the body. A second light emitting device is mount and stacked on the first light emitting device. The first light emitting device and the second light emitting device are electrically connected to the lead frame part. An encapsulating part covering the first light emitting device and the second light emitting device is formed on the body. The second light emitting device is stacked on the first light emitting device in such a manner that vertex portions of the upper light emitting device do not overlap and are offset from vertex portions of the first light emitting device, such that portions of the first light emitting device are externally exposed.

In the mounting and stacking of the second light emitting device, the second light emitting device is stacked on the first light emitting device, while being disposed in a state in which the second light emitting device is rotated with respect to the first light emitting device around an optical axis.

In the electrically connecting of the light emitting devices to the lead frame part, electrode pads provided on each of the first light emitting device and the second light emitting device and the lead frame part may be wire-bonded to one another.

The electrode pads of the first light emitting device may be provided on the portions of the first light emitting device externally exposed. The electrode pads of the second light emitting device may be provided on portions of the second light emitting device corresponding to the externally exposed portions of the first light emitting device.

Still another aspect of the present disclosure relates to a light emitting device package including a body including a lead frame part, and a light emitting laminate disposed on the body and electrically connected to the lead frame part, to emit light. The light emitting laminate has a multilayer structure in which a plurality of light emitting devices are stacked. In the plurality of light emitting devices, an upper light emitting device is stacked on a lower light emitting device in which the upper light emitting device is rotated with respect to the lower light emitting device around an optical axis, such that portions of the lower light emitting device are externally exposed without being covered by the upper light emitting device.

Vertex portions of the upper light emitting device may not overlap and may be offset from vertex portions of the lower light emitting device.

The upper light emitting device may be rotated with respect to the lower light emitting device within an angle range of 1 to 90°.

Each of the plurality of light emitting devices may include electrode pads at the vertex portions thereof externally exposed, the electrode pads being electrically connected to the lead frame part.

### BRIEF DESCRIPTION OF DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a perspective view schematically illustrating a light emitting device package according to an exemplary embodiment of the present disclosure.

FIG. 2 is a cross-sectional view of FIG. 1.

FIG. 3A is a cross-sectional view schematically illustrating light emitting devices of FIG. 1.

FIGS. 3B and 3C are plan views schematically illustrating the light emitting devices of FIG. 3A.

FIGS. 4A and 4B are a plan view and a cross-sectional view schematically illustrating a light emitting laminate formed by stacking a plurality of light emitting devices of FIG. 1.

FIGS. 5A and 5B are a plan view and a cross-sectional view schematically illustrating modified examples of FIGS. 4A and 4B.

FIGS. 6A and 6B are a plan view and a cross-sectional view schematically illustrating modified examples of FIGS. 5A and 5B.

FIGS. 7A and 7B are a cross-sectional view schematically illustrating a junction layer of FIG. 2, including a filler layer.

FIGS. 8A and 8B are a cross-sectional view and a plan view, respectively, schematically illustrating another embodiment of FIG. 2.

FIGS. 9A and 9B are a cross-sectional view and a plan view, respectively, schematically illustrating another embodiment of FIG. 2.

FIGS. 10 through 14 are views schematically illustrating respective processes of a method of manufacturing the light emitting device package according to an exemplary embodiment of the present disclosure.

FIG. 15 is a perspective view schematically illustrating a lighting device in which the light emitting device package according to an exemplary embodiment of the present disclosure is used.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

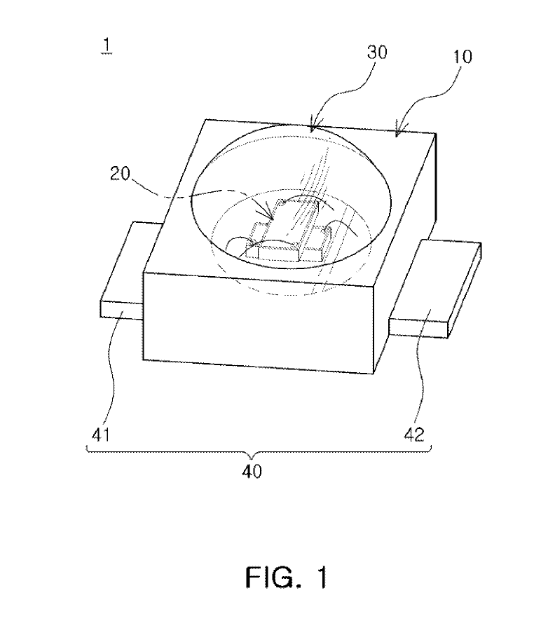

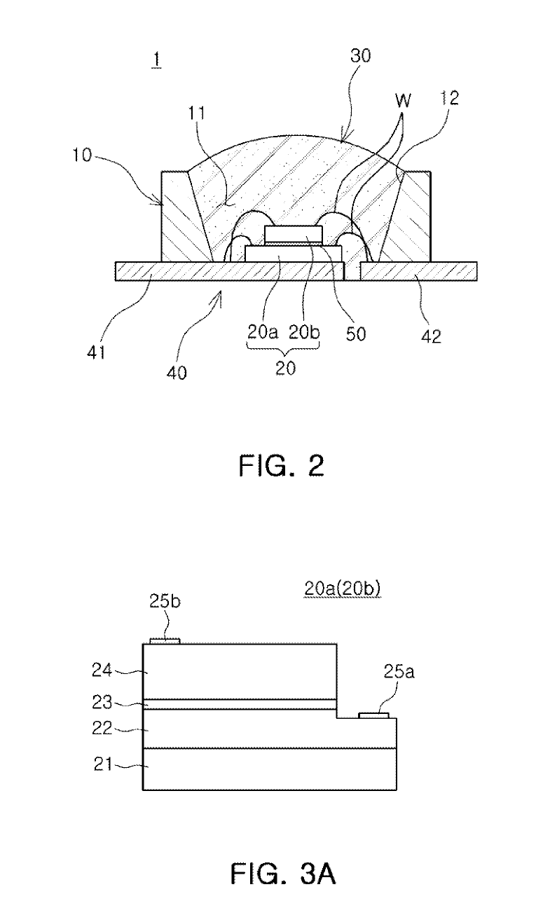

Referring to FIGS. 1 and 2, a light emitting device package according to an exemplary embodiment of the present disclosure will be described. FIG. 1 is a perspective view schematically illustrating a light emitting device package according to an exemplary embodiment of the present disclosure. FIG. 2 is a cross-sectional view of FIG. 1.

As shown in FIGS. 1 and 2, a light emitting device package 1 according to an exemplary embodiment of the present disclosure may include a body 10 including a lead frame part and a light emitting laminate 20 mounted on the body 10, and may further include an encapsulating part 30 covering the light emitting laminate 20.

The body 10 may be a base member having the light emitting laminate 20 disposed therein and supported thereby.

The body 10 may be formed of a white molding compound having high light reflectance, such that a quantity of light externally discharged due to reflection of light emitted from the light emitting laminate 20 may be increased. The white molding compound may include a high heat resistant thermosetting resin or silicon resin. Further, a thermoplastic resin with a white pigment, filler, a hardening agent, a release agent, an antioxidant, an adhesion improver, and the like may be added thereto. In addition, the white molding compound may be formed of FR-4, CEM-3, an epoxy material, a ceramic material or the like, and also may be formed of a metal such as aluminum (Al).

The body 10 may include a lead frame part 40 for electrical connection with an external power supply. The lead frame part 40 may be formed of a material having excellent electrical conductivity, for example, a metal material such as aluminum, copper, or the like.

The lead frame part 40 may be provided as at least one pair of lead frames separated from each other for electrical isolation therebetween and facing each other. For example, the lead frame part 40 may include a first lead frame 41 having a first polarity and a second lead frame 42 having a second polarity opposed to the first polarity. Here, the first polarity and the second polarity may be a positive polarity and a negative polarity, (or vice-versa) respectively. The first lead frame 41 and the second lead frame 42 may be separated from each other and electrically insulated from each other by the body 10.

The first and second lead frames 41 and 42 may be buried in the body 10 and fixed thereto. In addition, bottom surfaces of the first and second lead frames 41 and 42 may be externally exposed through a bottom surface of the body 10, whereby heat generated by the light emitting laminate 20 may be externally emitted and accordingly, heat radiation efficiency may be improved.

The body 10 may have a recess portion 11 (see FIG. 2) formed in an upper surface thereof, the recess portion 11 having the light emitting laminate 20 disposed therein. The recess portion 11 may have a cup (concave) shape in which an inner surface thereof is inclined and tapered toward the bottom surface of the body 10. The light emitting laminate 20 may be disposed on a lower surface of the recess portion 11.

The first and second lead frames 41 and 42 may be partially exposed to the lower surface of the recess portion 11. That is, portions of the first and second lead frames 41 and 42 may be exposed to the lower surface of the recess portion 11, to form the lower surface of the recess portion 11. In this case, the light emitting laminate 20 may be disposed on either of the first and second lead frames 41 and 42. Although the embodiment of FIG. 2 illustrates a case in which the light emitting laminate 20 is mounted on the first lead frame 41, but the present inventive concept is not limited thereto, and the light emitting laminate 20 may be mounted on the second lead frame 42.

Heat generated from the light emitting laminate 20 may be conducted to the first lead frame 41 and be externally discharged.

Referring to FIG. 2, the recess portion 11 may be provided with a reflective surface 12 surrounding the light emitting laminate 20. The reflective surface 12 may be formed to cover the inner surface of the recess portion 11 by coating, depositing, or attaching a high reflective material onto the inner surface of the recess portion 11. Alternatively, the reflective surface 12 may be selectively provided, or without the reflective surface 12, the inner surface of the recess portion 11 may serve as a reflective surface.

An embodiment of the present disclosure exemplifies a case in which the body 10 has the recess portion 11, but the present inventive concept is not limited thereto. For example, the body 10 may have a flat upper surface having no recess portion 11. In this case, the light emitting laminate 20 may be disposed on the upper surface of the body 10 and protrude upwardly therefrom.

The light emitting laminate 20 may be mounted on the body 10 and electrically connected to the lead frame part 40 to thereby emit light. The light emitting laminate 20 may be a laminate structure formed by vertically arranging a plurality of light emitting devices 20a and 20b.

As the light emitting devices 20a and 20b configuring the light emitting laminate 20, any photoelectric elements may be used, as long as they are able to generate a predetermined wavelength of light by external power applied thereto through the lead frame part 40. The light emitting devices 20a and 20b may include a semiconductor light emitting diode (LED) formed by epitaxial growing a semiconductor layer on a growth substrate 21. The light emitting devices 20a and 20b may emit red light, green light or blue light depending on a material contained therein, and may also emit white light.

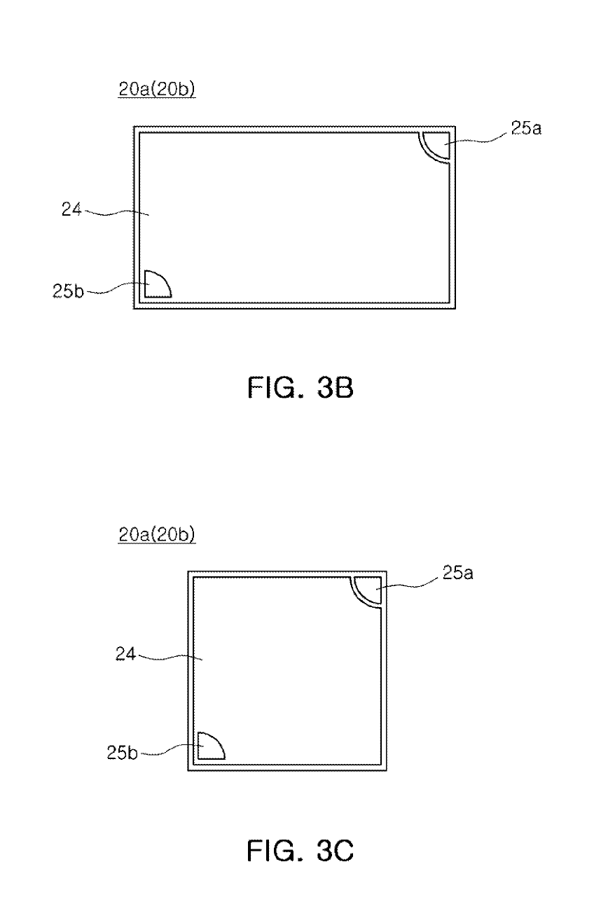

FIG. 3A schematically illustrates the light emitting devices. For example, as illustrated in FIG. 3A, the light emitting devices 20a and 20b may have a laminate structure including an n-type semiconductor layer 22, a p-type semiconductor layer 24, and an active layer 23 disposed therebetween, but the present inventive concept is not limited thereto. In addition, here, the active layer 23 may be formed of a nitride semiconductor having a single or multi-quantum well structure and including InₓAl_{y}Ga_{1-x-y}N (0≦x≦1, 0≦y≦1, 0≦x+y≦1).

As shown in FIG. 3B, the light emitting devices 20a and 20b may have a rectangular structure when viewed from above. In addition, as illustrated in FIG. 3C, the light emitting devices 20a and 20b may have a square structure when viewed from above. The present inventive concept is not limited thereto and such a structure of the light emitting devices may be variously changed.

The light emitting devices 20a and 20b may include a plurality of electrode pads 25a and 25b for electrical connection with the lead frame part 40. The electrode pads 25a and 25b may include an n-type electrode pad 25a and a p-type electrode pad 25b provided on an exposed surface of the n-type semiconductor layer 22 and one surface of the p-type semiconductor layer 24, respectively, and connected to the corresponding semiconductor layers 22 and 24. In this manner, since the electrode pads 25a and 25b may be disposed in the same direction, that is, in an upward direction from the exposed surface of the n-type semiconductor layer 22 and the one surface of the p-type semiconductor layer 24, the light emitting devices 20a and 20b may be an LED chip having a horizontal structure.

The plurality of electrode pads 25a and 25b may be provided at corners, edge regions, of the light emitting devices 20a and 20b. The embodiment of the FIGS. 3B and 3C exemplifies a case in which the plurality of electrode pads 25a and 25b are provided at corners of the light emitting devices 20a and 20b, but the present inventive concept is not limited thereto. For example, the plurality of electrode pads 25a and 25b may be respectively provided in the center of two facing edge surfaces and may also be provided at various positions.

In the following descriptions, the embodiment will be described on the basis that the light emitting devices 20a and 20b have a rectangular structure when viewed from above and include the electrode pads 25a and 25b at two corners thereof in a diagonal direction.

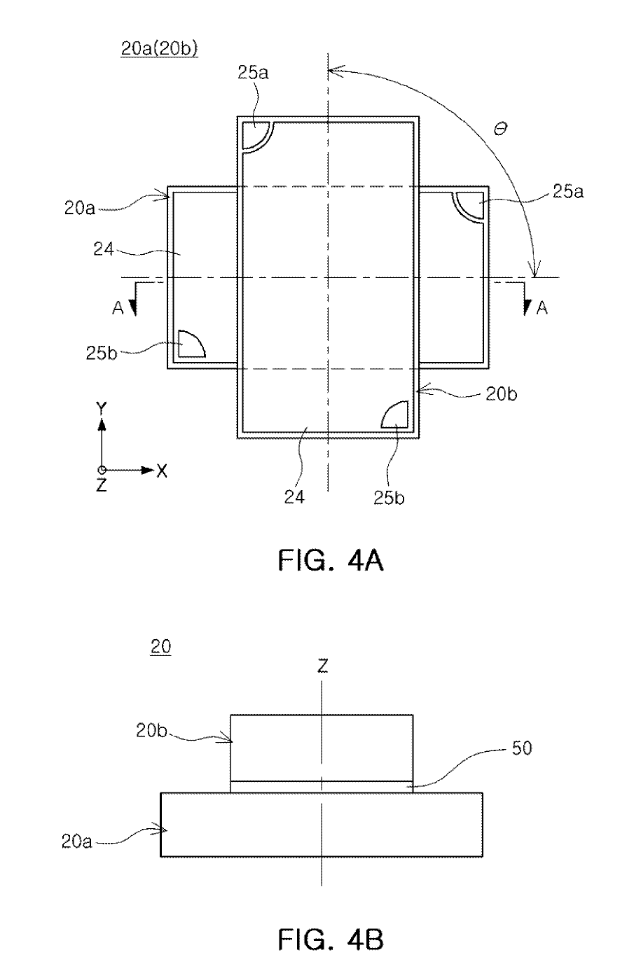

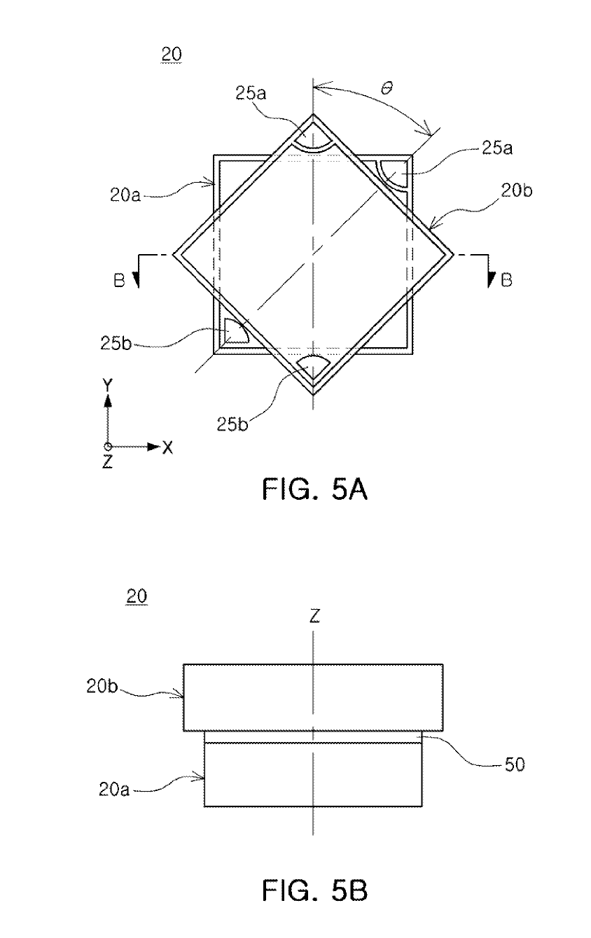

FIGS. 4A and 4B and FIGS. 5A and 5B respectively illustrate light emitting laminates formed by stacking a plurality of light emitting devices. FIG. 4B schematically illustrates a cutaway view of the light emitting laminate, taken along line X-X of FIG. 4A, and FIG. 5B schematically illustrates a cutaway view of the light emitting laminate, taken along line X-X of FIG. 5A.

As illustrated in FIGS. 4A and 4B and FIGS. 5A and 5B, the light emitting laminate 20 may include at least two vertically arranged light emitting devices 20a and 20b, and the light emitting devices 20a and 20b may be stacked in a vertical direction to form a multilayer structure.

The plurality of light emitting devices 20a and 20b may have the same size and shape as each other. For example, the light emitting devices 20a and 20b may have a rectangular shape as illustrated in FIGS. 4A and 4B, or may have a square shape as illustrated in FIGS. 5A and 5B. However, the light emitting devices may be variously formed.

According to FIGS. 4B and 5B, although sizes of the light emitting devices 20a and 20b are illustrated as being different from each other, FIGS. 4B and 5B are cutaway views of the light emitting devices, taken along line X-X of FIGS. 4A and 5A, and the size and the shape of the stacked light emitting devices 20a and 20b may be the same.

The plurality of the light emitting devices 20a and 20b may be variously configured such as being the same type of light emitting device, generating the same wavelength of light, or being different types of light emitting device, generating different wavelengths of light.

For example, each of the plurality of light emitting devices 20a and 20b may include a blue LED chip and may be covered by a wavelength conversion layer containing phosphors to thereby emit white light. The wavelength conversion layer may serve to convert a wavelength of light emitted from the light emitting devices 20a and 20b and to this end, one or more phosphors may be distributed within a transparent resin. In addition, light of which the wavelength has been converted by the wavelength conversion layer may be mixed with light emitted from the light emitting devices 20a and 20b to thereby implement white light.

For example, when the light emitting device 20a or 20b is a blue LED chip emitting blue light, a yellow phosphor may be used therein. Besides, in the case of a UV LED chip emitting ultraviolet light, red, green, and blue phosphors may be mixed to be used.

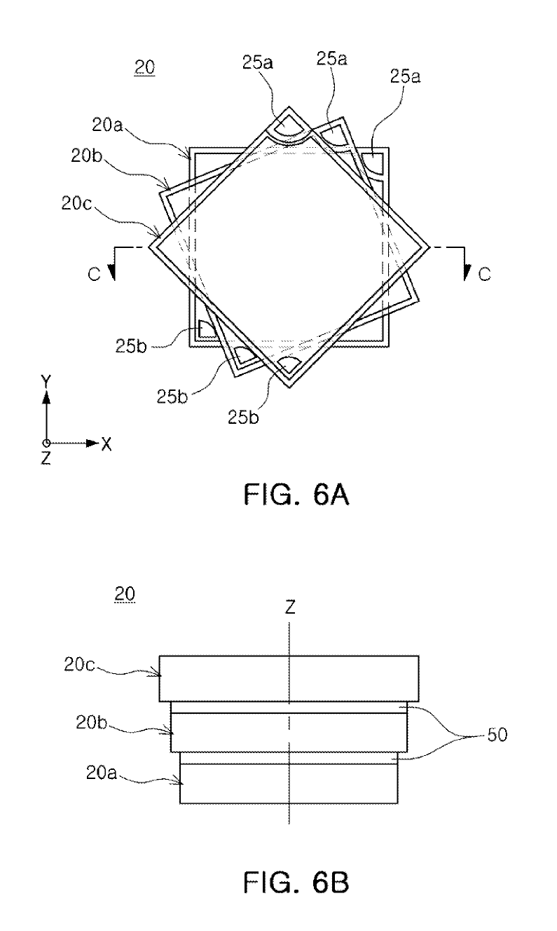

Further, as illustrated in FIGS. 6A and 6B, in order to implement white light, a plurality of light emitting devices 20a, 20b and 20c may include a red LED chip, a green LED chip, and a blue LED chip, respectively, and have a structure in which three chips are laminated. In addition, different wavelengths of light generated from the respective LED chips, that is, red light, green light, and blue light may be mixed to thereby implement a desired white light.

Meanwhile, in the plurality of light emitting devices 20a and 20b, the upper light emitting device 20b may be stacked on the lower light emitting device 20a in such a manner that corners the upper light emitting device 20a do not overlap and are offset from those of the lower light emitting device 20a, such that portions of the lower light emitting device 20a may be externally exposed, without being covered by the upper light emitting device 20b. Namely, the light emitting devices having a quadrangle shape may be stacked in such a manner that four corners and vertices thereof do not coincide with and are offset from one another. Thus, when viewed from above, the corners and vertex portions of the lower light emitting device 20a may be partially exposed from below of the upper light emitting device 20b.

In this manner, a structure in which the plurality of light emitting devices 20a and 20b are stacked in such a manner that the corners and vertex portions thereof do not coincide with and are offset from one another may be exemplified as a case in which the upper light emitting device 20b of the plurality of light emitting devices 20a and 20b is disposed in a state in which it is rotated with respect to the lower light emitting device 20a around an optical axis Z, as illustrated in FIGS. 4A and 5A.

By way of example, the upper light emitting device 20b may be vertically stacked on the lower light emitting device 20a along the optical axis Z, while being stacked in a state in which it is rotated with respect to the stationary lower light emitting device 20a around the optical axis Z as a central axis, in a range of a predetermined angle θ (see FIGS. 4A and 5A).

The rotating angle of the stacked light emitting device may be variously changed within a predetermined angle. For example, when the light emitting devices have a rectangular shape as illustrated in FIG. 4A, the upper light emitting device may be stacked in a state in which it is rotated with respect to the lower light emitting device within an angle range of 1 to 90°. Further, in a case in which the light emitting devices have a square shape as illustrated in FIG. 5A, the upper light emitting device may be stacked in a state in which it is rotated with respect to the lower light emitting device within an angle range of 1 to 45°. In this manner, the rotating angle θ of the stacked light emitting device may be variously adjusted depending on a size and a shape of the light emitting device.

Meanwhile, in the lower light emitting device 20a, corner portions including four vertices may be partially externally exposed without being covered by the upper light emitting device 20b. In this case, the plurality of electrode pads 25a and 25b of the light emitting devices 20a and 20b may be provided at two corners facing each other, among the four corners externally exposed. Thus, the plurality of light emitting devices 20a and 20b may be stacked in such a manner that the electrode pads 25a and 25b thereof are externally exposed, and may be electrically connected to the lead frame part 40 by bonding wires W.

The embodiment of FIGS. 3A-6B exemplifies that the electrode pads 25a and 25b are provided at two corners, among four corners, facing each other in a diagonal direction, but the present inventive concept is not limited thereto.

In this manner, the light emitting devices 20a and 20b may be vertically stacked and arranged in a state in which the upper light emitting device is rotated with respect to the lower light emitting device, whereby light irradiated externally from the light emitting devices 20a and 20b may entirely implement a circular-shaped distribution of light or a distribution of light in an approximately circular shape. That is, a single light emitting device having a square shape may implement a square-shaped distribution of light corresponding to the shape thereof, and square-shaped distributions of light implemented by the plurality of respective light emitting devices according to a rotation and disposition structure of the stacked light emitting devices may not entirely overlap and coincide with one another due to the rotation, thereby implementing a circular-shaped distribution of light overall.

Meanwhile, referring to FIGS. 4B, 5B and 6B, a junction layer 50 may be interposed between the plurality of the stacked light emitting devices 20a and 20b. The plurality of light emitting devices 20a and 20b may be adhered and fixed to each other by the junction layer 50 in a stacking process thereof. The junction layer 50 may include a die attach film (DAF), such that a multi-chip stack package structure may be formed. The junction layer 50 may be formed of a material having electrical insulating and heat resistant properties. The junction layer 50 may have a thickness of 1 μm to 50 μm.

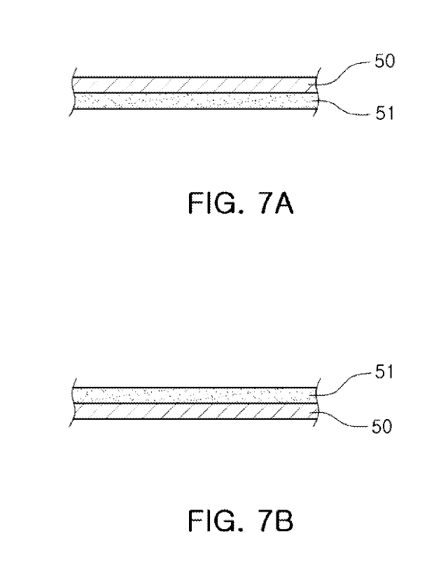

As illustrated in FIGS. 7A and 7B, a filler layer 51 may be added to one surface of the junction layer 50. The filler layer 51 may serve to reinforce the thickness and strength of the junction layer 50.

The filler layer 51 may be formed of the same material as the material of the junction layer 50 and contain filler therein. The filler may be formed of a non-conductive material including, for example, silica (SiO₂).

Referring to FIGS. 1 and 2, the encapsulating part 30 may be formed on the body 10 so as to cover the light emitting laminate 20.

The encapsulating part 30 may be formed of a transparent or semitransparent material in order to enable light generated from the light emitting laminate 20 to be emitted externally, and for example, may be formed of a resin such as silicon or epoxy.

The encapsulating part 30 may contain a wavelength conversion material excited by light emitted from the light emitting laminate 20 and externally emitting a different wavelength of light, for example, one or more phosphors. In addition, the encapsulating part 30 may contain a light reflective material. The light reflective material may include SiO₂, Al₂O₃, TiO₂ and the like.

The embodiment of FIGS. 1 and 2 exemplifies that the encapsulating part 30 has a convex lens structure, but the present inventive concept is not limited thereto. The encapsulating part 30 may have a flat shape corresponding to the upper surface of the body. A separate lens may be additionally attached to the upper surface of the body.

In the light emitting device package 1 according to an embodiment of the present disclosure, the plurality of light emitting devices 20a and 20b may form a laminate structure, such that a multi-chip package having high efficiency and high light output may be implemented, irrespectively of a mounting area. Therefore, the problem that a multi-chip package may not be implemented in the case of a small mounting area according to the related art may be solved.

In particular, the plurality of light emitting devices 20a and 20b may be arranged vertically and stacked in such a manner that one light emitting device is disposed in a state in which it is rotated with respect to the other light emitting device around the central optical axis Z, at a predetermined angle θ, whereby light irradiated from the light emitting devices 20a and 20b may entirely implement a circular-shaped distribution of light or a distribution of light in an approximately circular shape. In addition to this, light extraction efficiency may be entirely improved, because light emitting surfaces of the stacked light emitting devices 20a and 20b do not overlap one another due to the rotation and disposition of the light emitting device and accordingly, an area of the light emitting surfaces externally exposed is increased.

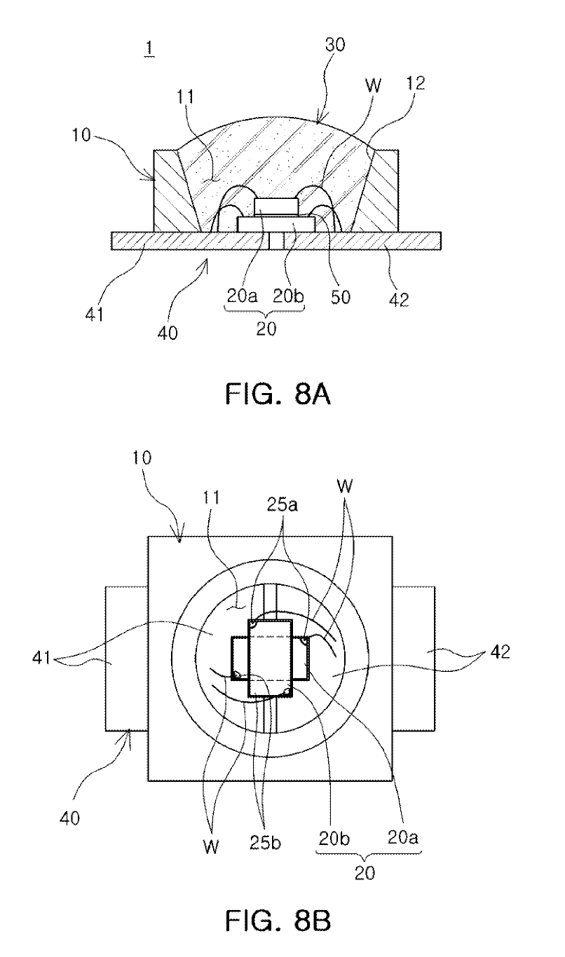

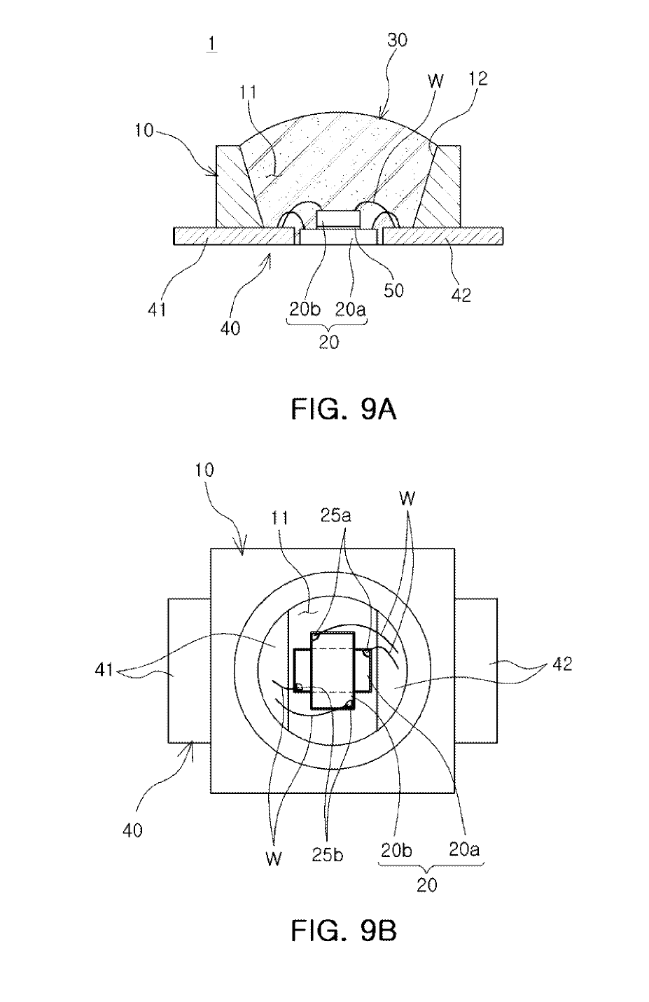

FIGS. 8 and 9 schematically, respectively, illustrate modified examples of the light emitting device package according to an exemplary embodiment of the present disclosure. Structures of the light emitting device package according to embodiments illustrated in FIGS. 8 and 9 may be substantially the same as that of the embodiment of FIG. 1 in terms of a basic structure thereof, but may be different in terms of a mounting position of the light emitting laminate.

As illustrated in FIGS. 8A and 8B, the light emitting laminate 20 may be mounted on portions of the first lead frame 41 and the second lead frame 42.

In addition, as illustrated in FIGS. 9A and 9B, the light emitting laminate 20 may not be mounted on the lead frame part 40. That is, the light emitting laminate 20 may be disposed between the first lead frame 41 and the second lead frame 42, may not directly contact the lead frame part 40, and may be encased in the encapsulating part 30 to be fixed therein. In this case, a lower surface of the light emitting laminate 20 may be directly exposed to the bottom surface of the body 10.

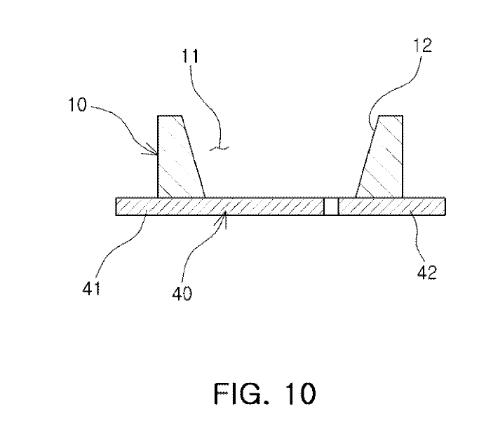

Referring to FIGS. 10 to 14, a method of manufacturing the light emitting device package according to an exemplary embodiment of the present disclosure will be described. FIGS. 10 through 14 are views schematically illustrating respective processes of a method of manufacturing the light emitting device package according to the exemplary embodiment of the present disclosure.

First, as illustrated in FIG. 10, the body 10 including the lead frame part 40 may be prepared.

The body 10 may be a base member having the light emitting laminate 20 mounted therein and supported thereby. The body 10 may be formed of a white molding compound having high light reflectance, such that a quantity of light externally discharged through reflection of light emitted from the light emitting laminate 20 may be increased. In addition, the body 10 may be formed of a metal such as aluminum (Al) in order to significantly increase heat radiation efficiency.

The body 10 may have the recess portion 11 receiving the light emitting laminate 20 therein and having a reflective cup (concave) structure. The recess portion 11 may selectively have the reflective surface 12 formed on an inner portion thereof.

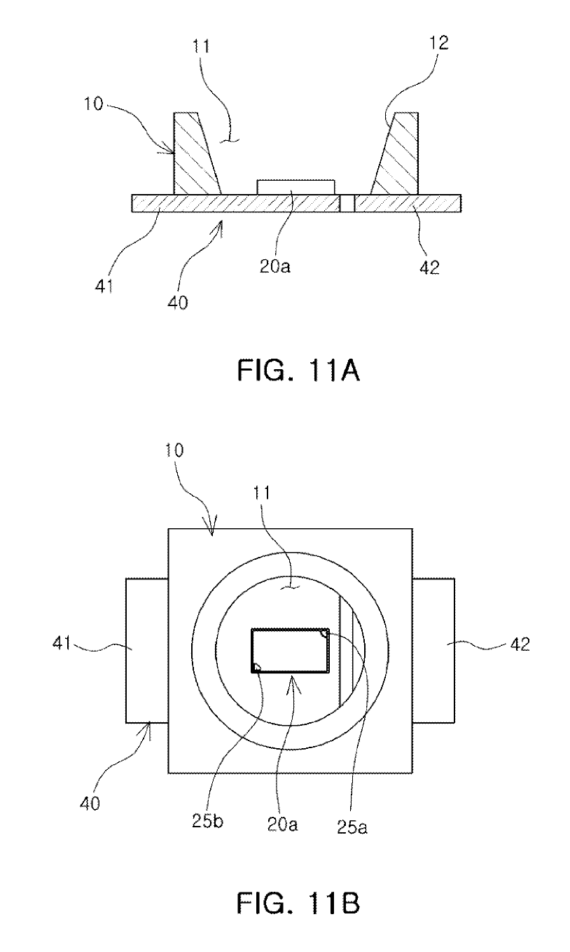

Then, as illustrated in FIGS. 11A and 11B, the light emitting device 20a (hereinafter, referred to as ‘a first light emitting device 20a’) may be mounted on the body 10. The first light emitting device 20a may have a laminate structure including the n-type semiconductor layer 22, the p-type semiconductor layer 24, and the active layer 23 disposed therebetween.

The first light emitting device 20a may include the plurality of electrode pads 25a and 25b for electrical connection with the lead frame part 40. The electrode pads 25a and 25b may include the n-type electrode pad 25a and the p-type electrode pad 25b provided on an exposed surface of the n-type semiconductor layer 22 and one surface of the p-type semiconductor layer 24, respectively, and connected to the corresponding semiconductor layers 22 and 24.

The plurality of electrode pads 25a and 25b may be disposed on the first light emitting device 20a in the same direction, that is, in an upward direction from the exposed surface of the n-type semiconductor layer 22 and the one surface of the p-type semiconductor layer 24, respectively. The plurality of electrode pads 25a and 25b may be provided at corners corresponding to edge regions, of the first light emitting device 20a, for example, at two vertex portions facing each other in a diagonal direction.

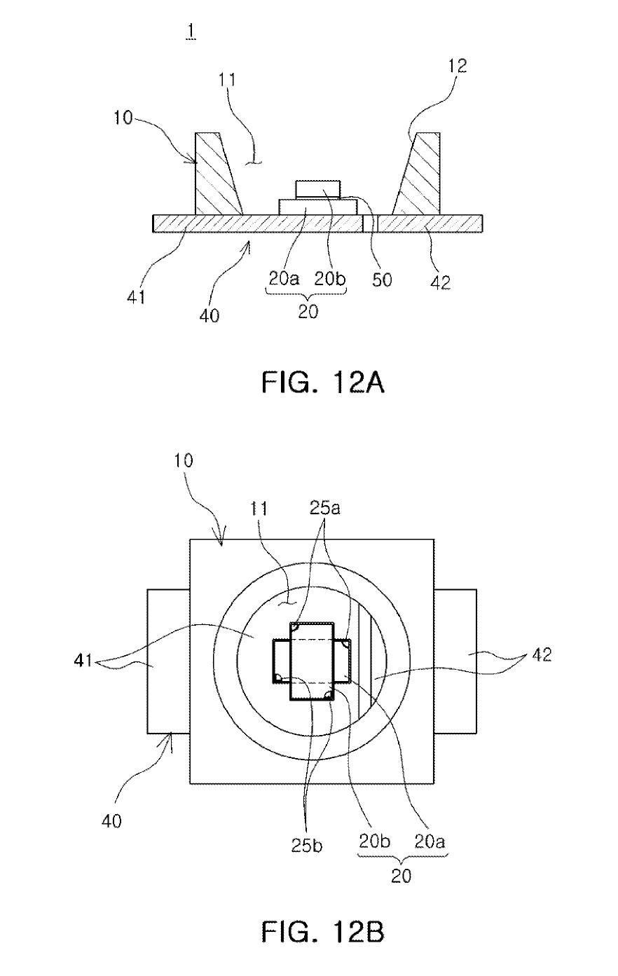

Next, as illustrated in FIG. 12A and FIG. 12B, the light emitting device 20b (hereinafter, referred to as ‘a second light emitting device 20b’) may be mounted and stacked on the first light emitting device 20a. The second light emitting device 20b may have the same size and shape as those of the first light emitting device 20a. In a similar manner to the case of the first light emitting device 20a, the second light emitting device 20b may include the electrode pads 25a and 25b at two vertex portions facing each other among corner portions thereof. That is, the second light emitting device 20b may be substantially the same as the first light emitting device 20a.

The junction layer 50 may be interposed between the first and second light emitting devices 20a and 20b.

Meanwhile, the second light emitting device 20b may be stacked on the first light emitting device 20a in such a manner that the vertex portions thereof do not overlap and are offset from the vertex portions of the first light emitting device 20a. Thus, the upper surface of the first light emitting device 20a may not be entirely covered by the second light emitting device 20b and partial regions thereof may be externally exposed.

By way of example, the second light emitting device 20b may be stacked on the first light emitting device 20a while being disposed in a state in which the second light emitting device 20b is rotated with respect to the first light emitting device 20a around the optical axis at a predetermined angle. When viewed from above, portions of the first light emitting device 20a may be exposed from the lower portion of the second light emitting device 20b. For example, four vertex portions and corner portions of the first light emitting device 20a may be partially exposed.

Therefore, the electrodes pads 25a and 25b may be provided on the portions of the first light emitting device 20a externally exposed, and other electrode pads 25a and 25b may be provided on portions of the second light emitting device 20b corresponding to the outwardly exposed portions of the first light emitting device 20a.

Although an embodiment of the present disclosure illustrates a chip stack structure in which the light emitting laminate 20 includes two first and second light emitting devices 20a and 20b stacked therein, the present inventive concept is not limited thereto. For example, another light emitting device, that is, a third light emitting device, may be further mounted on the second light emitting device 20b. In addition, another light emitting device may be successively mounted on the third light emitting device.

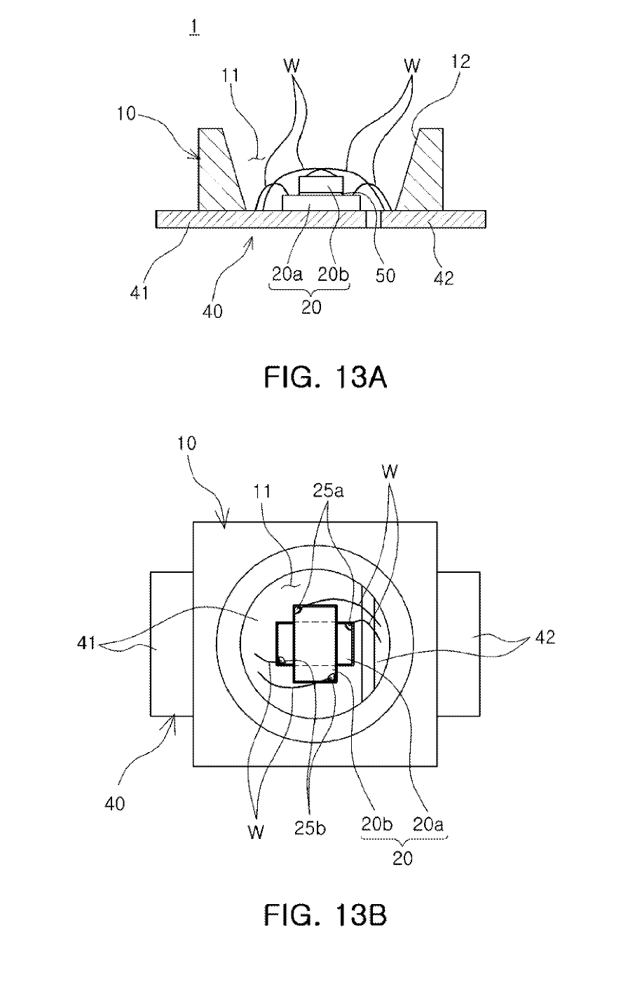

Next, as illustrated in FIGS. 13A and 13B, the first light emitting device 20a and the second light emitting device 20b may be electrically connected to the lead frame part 40. For example, the electrode pads 25a and 25b provided on each of the first light emitting device 20a and the second light emitting device 20b and externally exposed may be connected to the lead frame part 40 by the bonding of the wires W.

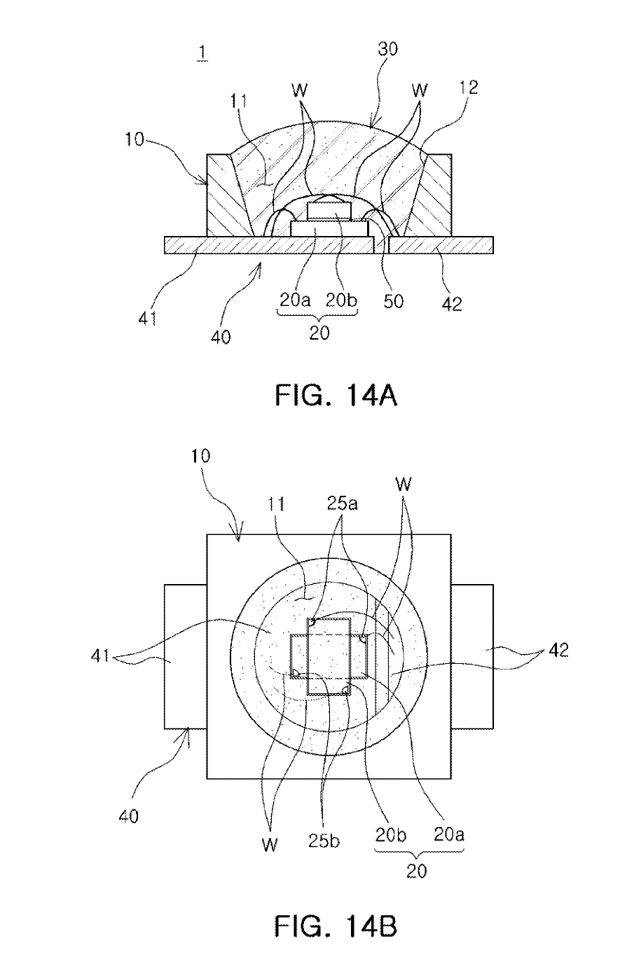

Then, as illustrated in FIGS. 14A and 14B, the encapsulating part 30 covering the first light emitting device 20a and the second light emitting device 20b may be formed on the body 10. The encapsulating part 30 may be formed by a method of injecting a fluidic solvent, for example, a resin, into the recess portion 11 and hardening the same.

The encapsulating part 30 may contain a light reflective material such as SiO₂, Al₂O₃, TiO₂ or the like, and may also contain one or more phosphors.

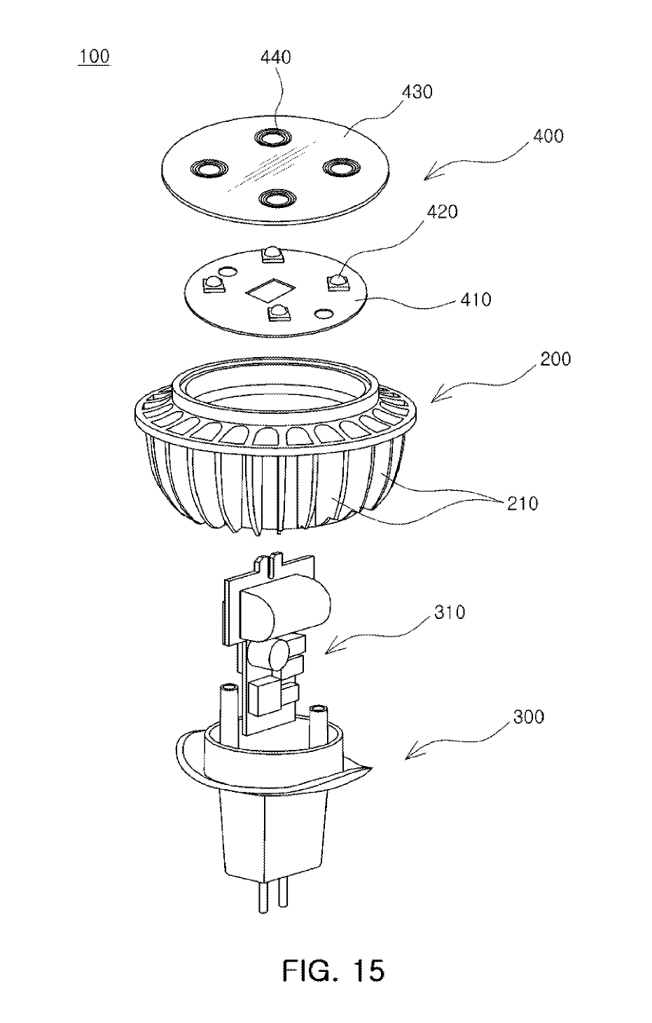

FIG. 15 is a perspective view schematically illustrating a lighting device in which the light emitting device package according to an exemplary embodiment of the present disclosure is used.

A lighting device 100 according to the present exemplary embodiment may be configured to include a heat sink 200, a housing 300 coupled to the rear of the heat sink 200, and a light source module 400 coupled to the front of the heat sink 200.

The heat sink 200 may have a hollow structure in which the center thereof is empty, and may be provided with a plurality of heat radiating fins 210 protruding radially from an outer lateral surface of the heat sink 200. The heat sink 200 may be formed of a material having excellent thermal conductivity such that heat generated from the light source module 400 may be externally discharged therethrough.

The housing 300 may be coupled to an external power source, for example, a power socket, to supply external power to the light source module 400. The housing 300 may be formed of an electrical insulating material such as plastic, a resin, or the like. A power supply unit (PSU) 310 may be accommodated in the housing 300.

The light source module 400 may be configured to include a substrate 410 mounted on the heat sink 200, a plurality of light emitting device packages 420 mounted on the substrate 410, and a cover 430 covering the plurality of light emitting device packages 420.

The substrate 410 may be a base member including a circuit board for mounting the light emitting device packages 420, and may be a so-called printed circuit board (PCB). The substrate 410 may be formed of a material such as FR-4, CEM-3, or the like, but the present inventive concept is not limited thereto. For example, the substrate 410 may be formed of a glass or epoxy material or a ceramic material. In addition, the substrate 410 may be formed of a material such as a metal or a metal compound, and include a metal core printed circuit board (MCPCB) and the like.

The light emitting device packages 420 may be mounted on the substrate 410 and may emit light by power applied thereto through the power supply unit (PSU) 310. A structure and configuration of the light emitting device package 420 is illustrated and described with reference to FIGS. 1 through 14, and thus, a detailed description thereof may be omitted.

The cover 430 may be formed of a transparent or semitransparent material in order to enable light generated from the light emitting device packages 420 to be emitted externally, and for example, may be formed of a resin such as silicon or epoxy, or a glass material.

The cover 430 may include lenses 440 so as to correspond the respective light emitting device packages 420. The lenses 440 may be disposed to face the respective light emitting device packages 420 and may adjust orientation angles of light generated from the light emitting device packages 420. The embodiment of FIG. 15 illustrates a structure in which the cover 430 is provided with the lenses 440 corresponding to the respective light emitting device packages 420, but the present inventive concept is not limited thereto. Although not illustrated in the drawings, the cover 430 may have a protrusion structure such as a convex lens shape in order to serve as a lens itself.

The cover 430 may contain a light diffusing agent. The light diffusing agent may have a particle size on a nano-level and may include one or more materials selected from a group consisting of SiO₂, TiO₂ and Al₂O₃.

The lighting device using LEDs as described above may be classified as an indoor lighting device or an outdoor lighting device. Indoor LED lighting devices may be generally provided to replace or retrofit existing lighting devices, and may include lamps, fluorescent lamps (LED-tubes), and flat type illumination devices. Outdoor LED lighting devices may include street lamps, security lamps, floodlighting lamps, scenery lamps, traffic lights, and the like.

The lighting device using LEDs may be employed as internal or external light sources of vehicles. Internal light sources of vehicles may include indoor lights, reading lights, gauge light sources, and the like. External light sources of vehicles may include various light sources such as headlights, break lights, turn indicators, fog lights, running lights and the like.

In addition, as light sources used for robots or various mechanical devices, LED lighting devices may be used. In particular, LED lighting devices using specific waveform bands may promote the growth of plants and may stabilize emotions or treat illnesses in humans.

Optical designs of LED lighting devices may be changed depending on product forms, intended locations, and objects thereof. With regard to mood lighting devices, controlling of such lighting devices may be performed using technologies of controlling a color, a temperature, and brightness of the lighting device, and a wireless (remote) control technology employing cellular phones such as smartphones.

In addition thereto, communication functions may be added to the LED lighting devices and display devices to thereby allow for the visible light wireless communication technology intended to simultaneously achieve essential purposes of an LED light source and purposes thereof as a communications means. This is because LED light sources may be advantageous, in that they have relatively long lifespans as compared to existing light sources and excellent power efficiency, allow for the implementation of various colors of light, have a high switching speed for digital communications, and enable digital controlling.

The visible light wireless communications technology may be a wireless communications technology wirelessly transmitting information using light within the visible light wavelength band. The visible light wireless communications technology may be differentiated from existing wired optical fiber communications and infrared wireless communications technologies in that it uses light within visible light wavelength bands, and may be differentiated from wired optical fiber communications technology in terms of wireless communications environments thereof.

In addition, the visible light wireless communications technology may have convenience in that it can be freely used without regulations or permission in terms of the frequency of use thereof, unlike in radio frequency (RF) wireless communications, and may have distinction in that physical security is excellent and communication links are able to be determined by a user's eyes. Furthermore, the visible light wireless communications technology may have characteristics as a fused technology capable of simultaneously achieving essential purposes of a light source and communications functions thereof.

As set forth above, according to exemplary embodiments of the present disclosure, a light emitting device package capable of realizing a multi-chip package by having a plurality of light emitting devices mounted therein, irrespectively of a bottom surface size of the package, and being easily miniaturized, and a method of manufacturing the same may be provided.

Various advantages and effects in exemplary embodiments of the present disclosure are not limited to the above-described descriptions and may be easily understood through explanations of concrete embodiments of the present disclosure.

While exemplary embodiments have been shown and described above, it will be apparent to those skilled in the art that modifications and variations could be made without departing from the spirit and scope of the present disclosure as defined by the appended claims.

What is claimed is:

1. A light emitting device package, comprising:
a body including a lead frame part; and
a light emitting laminate disposed on the body and electrically connected to the lead frame part, to emit light,
wherein the light emitting laminate has a multilayer structure in which a plurality of light emitting devices are stacked, and
in the plurality of light emitting devices, an upper light emitting device is stacked on a lower light emitting device such that vertex portions of the upper light emitting device do not overlap and are offset from vertex portions of the lower light emitting device, and portions of the lower light emitting device are externally exposed.

2. The light emitting device package of claim 1, wherein in the plurality of light emitting devices, the upper light emitting device is stacked on the lower light emitting device, while being disposed in a state in which the upper light emitting device is rotated with respect to the lower light emitting device, around an optical axis.

3. The light emitting device package of claim 2, wherein the upper light emitting device is rotated with respect to the lower light emitting device within an angle range of 1 to 90°.

4. The light emitting device package of claim 1, wherein each of the plurality of light emitting devices includes electrode pads at the vertex portions thereof externally exposed, the electrode pads being electrically connected to the lead frame part.

5. The light emitting device package of claim 1, wherein the plurality of light emitting devices are configured to emit white light.

6. The light emitting device package of claim 1, wherein the plurality of light emitting devices include a red light emitting diode (LED) chip, a green LED chip, and a blue LED chip.

7. The light emitting device package of claim 1, wherein each of the plurality of light emitting devices includes a blue LED chip and is covered by a wavelength conversion layer containing a phosphor.

8. The light emitting device package of claim 1, further comprising: a junction layer interposed between the plurality of the light emitting devices.

9. The light emitting device package of claim 8, further comprising: a filler layer disposed on one surface of the junction layer.

10. The light emitting device package of claim 1, wherein the body has a recess portion having the plurality of light emitting devices disposed therein, the recess portion including a reflective surface surrounding the plurality of light emitting devices.

11. The light emitting device package of claim 1, further comprising: an encapsulating part disposed on the body to cover the plurality of light emitting devices.

12. A method of manufacturing a light emitting device package, the method comprising:
preparing a body including a lead frame part;
mounting a first light emitting device on the body;
mounting and stacking a second light emitting device on the first light emitting device;
electrically connecting the first light emitting device and the second light emitting device to the lead frame part; and
forming an encapsulating part covering the first light emitting device and the second light emitting device on the body;
wherein the second light emitting device is stacked on the first light emitting device in such a manner that vertex portions of the upper light emitting device do not overlap and are offset from vertex portions of the first light emitting device, such that portions of the first light emitting device are externally exposed.

13. The method of claim 12, wherein in the mounting and stacking of the second light emitting device, the second light emitting device is stacked on the first light emitting device, while being disposed in a state in which the second light emitting device is rotated with respect to the first light emitting device around an optical axis.

14. The method of claim 12, wherein in the electrically connecting of the light emitting devices to the lead frame part,
electrode pads provided on each of the first light emitting device and the second light emitting device and the lead frame part are wire-bonded to one another.

15. The method of claim 14, wherein the electrode pads of the first light emitting devices are provided on the portions of the first light emitting device externally exposed, and the electrode pads of the second light emitting devices are provided on portions of the second light emitting device corresponding to the externally exposed portions of the first light emitting device.

16. A light emitting device package, comprising:
a body including a lead frame part; and
a light emitting laminate disposed on the body and electrically connected to the lead frame part, to emit light, wherein:
the light emitting laminate has a multilayer structure in which a plurality of light emitting devices are stacked, and
in the plurality of light emitting devices, an upper light emitting device is stacked on a lower light emitting device in which the upper light emitting device is rotated with respect to the lower light emitting device around an optical axis, such that portions of the lower light emitting device are externally exposed without being covered by the upper light emitting device.

17. The light emitting device package of claim 16, wherein vertex portions of the upper light emitting device do not overlap and are offset from vertex portions of the lower light emitting device.

18. The light emitting device package of claim 16, wherein the upper light emitting device is rotated with respect to the lower light emitting device within an angle range of 1 to 90°.

19. The light emitting device package of claim 17, wherein each of the plurality of light emitting devices includes electrode pads at the vertex portions thereof externally exposed, the electrode pads being electrically connected to the lead frame part.
